(19) United States
(12) Patent Application Publication
(10) Pub. No.: US 2025/0178980 A1
(43) Pub. Date: Jun. 5, 2025

(54) METHOD FOR STRUCTURING A METAL-CERAMIC COMPOSITE

(71) Applicant: Heraeus Electronics GmbH & Co. KG, Hanau (DE)

(72) Inventors: Richard WACKER, Hanau (DE); Bastian SCHLÜTER, Hanau (DE); Daniel SCHNEE, Hanau (DE)

(21) Appl. No.: 18/962,514

(22) Filed: Nov. 27, 2024

(30) Foreign Application Priority Data
Nov. 30, 2023 (EP) 23213369.4

(51) Int. Cl. C04B 41/88; C04B 41/00; C04B 41/91

(52) U.S. Cl. CPC C04B 41/88; C04B 41/0036; C04B 41/009; C04B 41/91

(57) ABSTRACT

A method for structuring a metal-ceramic composite, comprising the following steps:
providing a metal-ceramic composite containing
a nitride ceramic substrate comprising a front side and a rear side,
a metal coating on the front side of the nitride ceramic substrate,
a reaction layer which is present between the metal coating and the ceramic substrate and contains one or more elements E_{RS} selected from Ti, Hf, Zr, Nb, V, Ta, and Ce,
removing the metal coating so that at least one recess is created in the metal coating and an exposed adhesion-promoting layer is present in the recess,
removing the exposed reaction layer using a pulsed laser beam of an ultrashort pulse laser so that an exposed surface of the ceramic substrate is present in the recess, wherein the pulsed laser beam applies a total fluence of 50 J/cm² to 650 J/cm².

### CROSS-REFERENCE TO RELATED APPLICATIONS

This application claims priority pursuant to 35 U.S.C. 119(a) to European Patent Application No. 23213369.4, filed Nov. 30, 2023, which application is incorporated herein by reference in its entirety.

### FIELD OF THE INVENTION

The present invention relates to a method for structuring a metal-ceramic composite. Such structured metal-ceramic composites can be used as ceramic circuit carriers in semiconductor modules for power electronics.

### BACKGROUND OF THE INVENTION

In power electronics, printed circuit boards must be designed for high currents as carriers for power components, such as MOSFETs, and be able to quickly dissipate waste heat.

Since ceramic materials, such as aluminum oxide, aluminum nitride, and silicon nitride, have a much higher thermal conductivity than polymers used to produce conventional printed circuit boards, ceramic circuit carriers are often used in power modules.

A ceramic circuit carrier contains a ceramic substrate which is provided with a metal layer at least on the front side thereof. Conventionally, a metal layer is also applied to the rear side of the ceramic substrate. In the final module, the semiconductor components are applied to one of these metal layers, while the metal layer on the opposite side of the ceramic substrate is thermally conductively connected to a heat sink. The ceramic substrate electrically insulates the metal layers from each other.

Known to a person skilled in the art, a metalized ceramic substrate functioning as a ceramic circuit board is produced, for example, by bringing the front and rear side of the ceramic substrate into contact with a metal film (e.g., a copper or aluminum film) and bonding them together.

In one of these methods known to a person skilled in the art, the metal film is bonded to the ceramic substrate by eutectic bonding. If the metal film is a copper film, eutectic bonding is also referred to as the DCB or DBC method (DCB: “direct copper bonding”; DBC: “direct bonded copper”). In the case of aluminum film, the term “DAB” (“direct aluminum bonding”) is also used for eutectic bonding. A metalized ceramic substrate produced using a DCB method is sometimes also referred to as a DCB substrate (alternatively: DBC substrate).

Ceramic substrates based on a nitride (nitride ceramic substrates), such as aluminum or silicon nitride, are used as ceramic circuit carriers due to their advantageous properties.

For example, ceramic substrates based on silicon nitride have very high mechanical strength and at the same time high thermal conductivity and are therefore very suitable for applications in power electronics.

Ceramic substrates based on silicon nitride are described, for example, in the following publications:
N. Chasserio et al., “Ceramic Substrates for High-Temperature Electronic Integration,” Journal of Electronic Materials, Volume 38 (2009), pp. 164-174;
K. Hirao et al., “High Thermal Conductivity Silicon Nitride Ceramics,” Journal of the Korean Ceramic Society, Volume 49 (2012), pp. 380-384;
Y. Zhou et al., “Development of high-thermal-conductivity silicon nitride ceramics,” Journal of Asian Ceramic Societies, 3 (2015), pp. 221-229.

Ceramic substrates based on aluminum nitride have a very high thermal conductivity and at the same time sufficiently high mechanical strength and are therefore also very suitable for applications in power electronics.

However, silicon nitride substrates are not suitable for metalization using the DCB method and aluminum nitride substrates must first be oxidized on the surface, which, however, is complex and can have a negative impact on thermal conductivity.

Nitride ceramics are therefore often metalized by active metal brazing (AMB).

Active metal brazes are metal brazes which, due to their composition, are able to wet non-metallic, inorganic materials (e.g., ceramics, graphite, glass). Active metal brazes contain, in addition to a main component, such as Cu, Ag or Au, one or more elements that can react with the ceramic to form an adhesion-promoting reaction layer (see, for example, Chapter 8.2.4.3 (“Active metal brazing”), pages 203-204, in Brevier Technische Keramik, Verband der Keramischen Industrie eV, 2003, Fahner Verlag). Reactive elements, such as hafnium (Hf), titanium (Ti), zirconium (Zr), niobium (Nb), cerium (Ce), tantalum (Ta), and vanadium (V), are used. In the metalization of silicon nitride substrates by active metal brazing, the reaction layer contains, for example, a nitride, oxynitride and/or silicide of the reactive element (A. Pönicke et al., “Active metal brazing of copper with aluminum nitride and silicon nitride ceramics,” Keramische Zeitschrift, 63(5), 2011, 334-342).

The metal coating of the metal-ceramic composite carrying the semiconductor components is structured (e.g., by etching using an etching mask). A structured metal coating therefore has one or more recesses through which the regions of the metal coating remaining after structuring are separated from one another. The structuring of AMB substrates is usually carried out in a two-step method. For example, in a first step, a first etching solution is used which is optimized with regard to the removal of the metal coating. With this first etching solution, the metal coating is removed in defined (e.g., non-masked) regions and the reaction layer formed during active metal brazing is exposed. In a further step, the surface of the ceramic substrate is exposed using a second etching solution that is optimized with regard to removing the reaction layer.

For later use as a power electronics module, it is essential that adjacent conductor tracks formed by structuring are electrically insulated from each other. This in turn requires that no residues of the reaction layer remain between adjacent conductor tracks. The etching solution used in the second etching step should therefore completely remove the exposed reaction layer. However, this often results in under-etching of the metal coating, i.e., the etching solution of the second etching step not only removes the reaction layer exposed after the first etching step, but also removes a reaction layer on the flank of the metal coating that is still covered and thus required for the bond between the metal coating and the ceramic substrate. This can result in detachment of the metal coating from the ceramic substrate under thermal cycling stress.

For the etching process of the reaction layer resulting from the active metal brazing method, aggressive chemicals are required which can leave undesirable (e.g., corrosive) residues on the ceramic even after a final washing step. When using etching media containing fluoride, fluoride residues may remain on the exposed ceramic surface. Such etching agent residues can have a corrosive effect in a power electronics module.

When attempting to remove the reaction layer exposed after the first removal step as completely as possible in a further removal step, there is always a risk of damaging the ceramic substrate. This in turn can result in an impairment of the mechanical properties, such as the bending strength of the ceramic substrate.

An object of the present invention is that of structuring a metal-ceramic composite produced by active metal brazing by means of a method which allows for efficient exposure of the ceramic surface in defined regions, but does not achieve this at the expense of the thermal shock resistance of the metal-ceramic composite and/or the mechanical properties, such as the bending strength, of the ceramic substrate. Efficient exposure of the ceramic surface includes, in particular, that substantially no electrically conductive and/or corrosive materials remain on the exposed ceramic substrate surface.

The object is achieved by a method for structuring a metal-ceramic composite, which comprises the following steps:
providing a metal-ceramic composite containing
   a nitride ceramic substrate comprising a front side and a rear side,
   a metal coating on the front side of the nitride ceramic substrate,
   a reaction layer which is present between the metal coating and the ceramic substrate and contains one or more elements E_{RS} selected from Ti, Hf, Zr, Nb, V, Ta and Ce,
removing the metal coating so that at least one recess is created in the metal coating and an exposed adhesion-promoting layer is present in the recess,
removing the exposed reaction layer using a pulsed laser beam of an ultrashort pulse laser so that an exposed surface of the ceramic substrate is present in the recess, wherein the pulsed laser beam applies a total fluence of 50 J/cm² to 650 J/cm².

The metal-ceramic composite, which is structured in the method according to the invention by exposing the ceramic surface in defined regions, is a metal-ceramic composite produced by active metal brazing, wherein the ceramic is a nitride ceramic. Such metal-ceramic composites are known to a person skilled in the art and are commercially available or can be produced by known methods. The removal of the metal coating to expose the reaction layer resulting from the active metal brazing process can also be carried out using conventional removal methods (e.g., etching), as explained in more detail below.

In the present invention, it was found that the exposed reaction layer can be completely removed from the surface of the ceramic substrate and the bending strength of the ceramic substrate and the thermal shock resistance of the metal-ceramic composite can still be maintained at a high level if removal is carried out using an ultrashort pulse laser and the total fluence applied by the ultrashort pulse laser for exposing the ceramic substrate is 50 J/cm² to 650 J/cm².

An ultrashort pulse laser is a laser that can emit laser pulses with a pulse duration in the range of picoseconds (“picosecond laser”) or femtoseconds (“femtosecond laser”). As is known to a person skilled in the art, the fluence (or energy density) of a laser refers to the energy applied per unit area. For a pulsed laser beam, the fluence can refer to a single laser pulse or the totality of all laser pulses emitted during processing of a material. The latter is called total fluence or accumulated fluence and refers to the total energy per unit area applied by the pulsed laser beam into the irradiated region of the metal-ceramic composite.

The total fluence Fₜₒₜₐₗ results from the following relationship:

$${F}_{total} = {E}_{total} / {A}_{L}$$

where
Eₜₒₜₐₗ is the total energy applied by the pulsed laser beam and
A_{L} is the total area irradiated by the laser beam.

If the laser pulses of the pulsed laser beam each have the same pulse energy EP, the total fluence Ftotal results from the following relationship:

$${F}_{total} = {N}_{P} \times {E}_{P} / {A}_{L}$$

where
N_{P} is the total number of laser pulses applied by the pulsed laser beam,
E_{P} is the energy of a laser pulse,
A_{L} is the total area irradiated by the laser beam.

As described in more detail below, if the total fluence applied by the pulsed laser beam of the ultrashort pulse laser is less than 50 J/cm², the exposed reaction layer is not removed or is only insufficiently removed, whereas if the total fluence applied is more than 650 J/cm², the exposed reaction layer is completely removed, but the bending strength of the ceramic substrate deteriorates significantly.

The metal-ceramic composite to be structured in the method according to the invention contains
a nitride ceramic substrate comprising a front side and a rear side,
a metal coating on the front side of the nitride ceramic substrate and
a reaction layer which is present between the metal coating and the ceramic substrate and contains one or more elements E_{RS} selected from Ti, Hf, Zr, Nb, V, Ta and Ce.

The nitride ceramic substrate contains, for example, a silicon nitride or an aluminum nitride. In a preferred embodiment, the nitride ceramic substrate contains silicon nitride.

For example, the nitride ceramic substrate contains the silicon nitride or aluminum nitride in a proportion of at least 70 wt. %, more preferably at least 80 wt. %.

Optionally, the nitride ceramic substrate may contain one or more metal oxides. These were added, for example, as sintering aids during the production of the ceramic substrate. For example, the nitride ceramic substrate contains one or more of the following oxides: one or more alkaline earth metal oxides, such as magnesium oxide, one or more transition metal oxides (e.g., one or more rare earth oxides, such as yttrium oxide), a silicon oxide (e.g., SiO₂) or a silicate.

The nitride ceramic substrate, for example, has a thickness in the range of 0.1 mm to 1.0 mm.

There is a metal coating on the front side of the nitride ceramic substrate. Optionally, a metal coating is also available on the rear side of the ceramic substrate.

The metal coating present on the front side and optionally the rear side of the nitride ceramic substrate is, for example, a copper coating or an aluminum coating. The metal coating has, for example, a thickness in the range of 0.05 mm to 1.5 mm, more preferably 0.2 mm to 0.8 mm.

If the metal coating is a copper coating, it has, for example, a copper content of at least 97 wt. %, more preferably at least 99 wt. %.

If the metal coating is an aluminum coating, it has, for example, an aluminum content of at least 97 wt. %, more preferably at least 99 wt. %.

The metal coating is, for example, a copper film or an aluminum film that has been applied to the nitride ceramic substrate by active metal brazing.

The reaction layer contains one or more elements E_{RS}, selected from Hf, Ti, Zr, Nb, V, Ta, and Ce, preferably selected from Hf, Ti, Zr, Nb, and Ce, more preferably selected from Hf, Ti, and Zr. The element E_{RS} particularly preferred in the reaction layer is titanium. For example, the elements E_{RS} are present in the reaction layer in the form of a nitride, oxynitride, and/or silicide. For example, the reaction layer contains the elements E_{RS} in a total amount of at least 50 wt. %. For example, the reaction layer contains the nitrides, oxynitrides, and silicides of the elements E_{SR} in a total amount of at least 70 wt %, more preferably at least 85 wt. %. In a power electronics semiconductor module, the migration of silver can cause problems. It may therefore be preferred that the reaction layer contains silver in a proportion of no more than 5 wt. %, more preferably no more than 1 wt. %, or is even silver-free.

In the method according to the invention, the metal coating of the metal-ceramic composite provided is removed in defined regions (e.g., taking into account a specific desired conductor track arrangement) so that at least one recess is created in the metal coating and an exposed reaction layer is present in the recess.

The removal of the metal coating to form one or more recesses in the metal coating can be carried out by methods known to a person skilled in the art.

For example, the metal coating is removed by etching (e.g., using an etching mask so that the metal coating only comes into contact with the etching medium in the non-masked regions and is removed) or by laser ablation.

In a preferred embodiment, the metal coating is removed by etching. Suitable etching media and etching conditions for removing a metal coating (for example a copper or aluminum coating) are known to a person skilled in the art. For example, etching is carried out using an aqueous metal chloride solution (e.g., an aqueous iron chloride or copper chloride solution). However, other etching solutions known to a person skilled in the art can also be used. Etching can, if necessary, be carried out in several steps using different etching solutions. The etching continues until the reaction layer is exposed. With regard to the composition of the exposed reaction layer, reference can be made to the above statements.

The exposed reaction layer present in the recess is irradiated using a pulsed laser beam of an ultrashort pulse laser and removed so that a surface of the ceramic substrate in the recess is exposed. The surface of the ceramic substrate is exposed with a total fluence of 50 J/cm² to 650 J/cm² applied by the pulsed laser beam. With this applied total fluence, the exposed reaction layer can be completely removed from the surface of the ceramic substrate without affecting the bending strength of the ceramic substrate or the thermal shock resistance of the metal-ceramic composite.

In an exemplary embodiment, the total fluence applied by the pulsed laser beam is 100 J/cm² to 320 J/cm².

The pulsed laser beam of the ultrashort pulse laser, for example, has laser pulses with a pulse duration in the range of picoseconds (“picosecond laser”) or femtoseconds (“femtosecond laser”). For example, the pulse duration is 1 fs to 100 ps, more preferably 100 fs to 50 ps (e.g., 1 to 100 ps, more preferably 1 to 50 ps, or 1 to <1000 fs, more preferably 100 to <1000 fs).

Suitable laser operating parameters with which the total fluence applied can be adjusted are known to a person skilled in the art.

As mentioned above, the total fluence applied by the pulsed laser beam results from the total energy applied by the pulsed laser beam per unit area.

For example, the total fluence applied by the pulsed laser beam can be adjusted by one or more of the following parameters:
energy of a laser pulse,
pulse frequency (i.e., number of laser pulses per unit of time)
diameter of the laser beam hitting the surface of the material to be removed,
extent of spatial overlap of the laser pulses (e.g., the spatial overlap of successive laser pulses along a scan line or the spatial overlap between laser pulses of adjacent scan lines),
number of laser passes over the material to be removed,
scanning speed (i.e., the speed at which the pulsed laser beam is scanned over the material to be removed).

These parameters can be adjusted and varied on commercially available ultrashort pulse lasers by measures known to a person skilled in the art.

For example, the pulses of the pulsed laser beam each have a pulse energy of at least 15 μJ, more preferably at least 20 μJ, for example 15 μJ to 300 μJ, more preferably 20 μJ to 200 μJ.

For example, the pulsed laser beam has a pulse frequency of 100 kHz to 50 MHz, more preferably 500 kHz to 20 MHz.

The pulsed laser beam hitting the exposed adhesion-promoting layer has, for example, a diameter of 3 μm to 200 μm, more preferably 10 μm to 100 μm.

The diameter of the pulsed laser beam hitting the exposed reaction layer can be adjusted via the focus diameter of the laser beam. For example, the pulsed laser beam has a focus diameter of 3 μm to 200 μm, more preferably 10 μm to 100 μm, and the metal-ceramic composite is positioned so that the exposed reaction layer is in the focus of the pulsed laser beam.

The pulsed laser beam is guided, for example, along one or more scan lines (also referred to as processing lines or processing paths) over the exposed adhesion-promoting layer to be removed.

Preferably, the pulse frequency and the scanning speed of the pulsed laser beam are selected such that immediately successive laser pulses spatially overlap (i.e., the impact surfaces of the immediately successive laser pulses on the exposed adhesion-promoting layer overlap with one another).

The pulse overlap PO is usually given in % and can be calculated, for example, using the following equation:

$$PO = ( 1 - {v}_{scan} / ( {D}_{L} \times {f}_{L} ) ) \times 100 \%$$

where
ν_{scan} is the scanning speed of the pulsed laser beam (i.e., the speed at which the pulsed laser beam is guided over the exposed adhesion-promoting layer),
D_{L} is the diameter of the pulsed laser beam hitting the exposed adhesion-promoting layer,
f_{L} is the pulse frequency of the pulsed laser beam.

The pulse overlap PO can be adjusted for a specified laser beam diameter by the pulse frequency and scanning speed of the pulsed laser beam.

For example, in the method of the present invention, a pulse overlap of at least 60%, more preferably at least 80%, is chosen.

For example, the following relationship applies:

$$PO = ( 1 - {v}_{s c a n} / ( {D}_{L} \times {f}_{L} ) ) \times 100 \% \geq 60 \%$$

More preferably the following applies:

$$PO = ( 1 - {v}_{s c a n} / ( {D}_{L} \times {f}_{L} ) ) \times 100 \% \geq 80 \%$$

After exposing the front side of the ceramic substrate in the at least one recess, the structured metal-ceramic composite can, if necessary, be subjected to further treatment steps. For example, semiconductor components and/or metallic bonding wires can be applied to the structured metal coating.

### Measurement Methods

### Composition of the Reaction Layer

The composition of the adhesion-promoting layer is determined by energy-dispersive X-ray spectroscopy (EDX) coupled with scanning electron microscopy (SEM-EDX).

In SEM-EDX, a focused primary electron beam is guided (screened) over the sample surface point by point. The scattered electrons are detected using a detector, with the number of electrons per pixel resulting in a microscopic image of the sample surface in grayscale. In addition, the primary electron beam excites the sample to emit characteristic X-ray radiation, and the elements in the sample and their weight proportion can be determined by analyzing the energy spectrum using an EDX detector. For the examination, for example, a scanning electron microscope (JSM-6060 SEM, JEOL Ltd) with a silicon drift EDX detector (NORAN, Thermo Scientific Inc) and analytical software (Pathfinder Mountaineer EDS System, for example Version 2.8, Thermo Scientific Inc) are used. For scanning electron microscopy, the following settings are used: magnification: 1000-fold, acceleration voltage=15 kV, working distance=10 mm, spot size (50-60) (set to reach 25%+/−5% of the dead time of the EDX detector). The EDX spectrum was detected using the following settings of the EDX detector: live time=30 s, rate=auto, low energy cutoff=100 keV, high energy cutoff=auto (per SEM acceleration voltage).

By means of SEM-EDX, the composition of the reaction layer can be determined both qualitatively (detection of certain elements and phases, e.g. a metal nitride phase present in the adhesion-promoting layer) and quantitatively. For example, the measurement is carried out at at least 10 points on the reaction layer.

### EXAMPLES

In the examples described below, matching silicon nitride substrates were first metalized under identical conditions by active metal brazing with a copper film to obtain a copper-silicon nitride composite.

Metalization of the silicon nitride substrates by active metal brazing was carried out as follows:

On one of the sides of the ceramic substrate, an active metal brazing paste was applied by screen printing on an area measuring 168 mm×130 mm and pre-dried for 15 minutes at 125° C. The active metal brazing paste consisted of 67 wt. % copper powder, 19.8 wt. % tin powder, 3.7 wt. % titanium hydride and 9.5 wt. % of an organic vehicle. The paste thickness after pre-drying was 25+/−5 μm. Subsequently, a copper film made of oxygen-free, highly conductive copper with a purity of 99.99% and dimensions of 170 mm×132 mm×0.3 mm was placed on the pre-dried paste. The resulting arrangement was then turned over, the paste was similarly applied to the opposite side of the ceramic substrate by screen printing, pre-dried and fitted with a copper film to obtain a sandwich arrangement. The sandwich arrangement was weighted with a weight of 1 kg, fired at a maximum temperature of 910° C. for 20 minutes, and then cooled to room temperature to obtain an unstructured metal-ceramic composite. Due to the production by active metal brazing, an adhesion-promoting reaction layer is present between the metal coating and the ceramic substrate. This contains titanium (e.g., in the form of a nitride).

Subsequently, in each of the metal-ceramic composites provided, the metal coating was removed in a defined region under identical conditions, so that in each of the metal-ceramic composites at least one recess was created in the metal coating and an exposed reaction layer was present in the recess. The copper coating was removed using an etching solution containing CuCl₂.

The exposed reaction layer remaining on the ceramic substrate after etching was subsequently removed under different conditions.

In the examples EB-1.1, EB-1.2, EB-1.3, EB-1.4 and EB-1.5 according to the invention as well as the comparative examples VB-1.1, VB-1.2, and VB-1.3, the exposed reaction layer was removed using an IR ultrashort pulse laser (TruMicro Series 2000, Trumpf). These examples EB-1.1 to EB-1.5 and VB-1.1 to VB-1.3 matched in the following parameters:
Pulse duration: 3 ps
Focus diameter of the pulsed laser beam: 55 μm
Scanning speed: 5500 mm/s
Pulse frequency: 1 MHz
Pulse overlap: 90%
Distance between adjacent scan lines: 25 μm

However, the pulse energies and number of passes over the scan lines (i.e., how often the specified scan lines were passed over with the pulsed laser beam) were varied, so that in the examples EB-1.1 to EB-1.5 according to the invention a total fluence in the range of 50-650 J/cm² was applied, while in comparative example VB-1.1, a lower total fluence was applied and in comparative example VB-1.2, a higher total fluence was applied.

In the examples EB-2.1, EB-2.2, EB-2.3, EB-2.4, and EB-2.5 according to the invention as well as the comparative examples VB-2.1 and VB-2.2, the exposed reaction layer was also removed using the IR ultrashort pulse laser (TruMicro Series 2000, Trumpf). These examples EB-2.1 to EB-2.5 and VB-2.1 to VB-2.2 matched in the following parameters:
Pulse duration: 850 fs
Focus diameter of the pulsed laser beam: 55 μm
Scanning speed: 1100 mm/s
Pulse frequency: 5 MHz
Pulse overlap: 90%
Distance between adjacent scan lines: 15 μm

Again, the pulse energies and number of passes over the scan lines by the pulsed laser beam were varied, so that in the examples EB-2.1 to EB-2.5 according to the invention a total fluence in the range of 50-650 J/cm² was applied, while in comparative example VB-2.1, a lower total fluence was applied and in comparative example VB-2.2, a higher total fluence was applied.

In comparative example VB3, the exposed reaction layer was removed with an etching solution containing ammonium fluoride, fluoroboric acid, and hydrogen peroxide.

Each of the structured metal-ceramic composites obtained after removal of the reaction layer was investigated with regard to the following properties:
possible residues of the exposed reaction layer on the ceramic substrate,
   bending strength of the ceramic substrate,
   thermal shock resistance of the metal-ceramic composite.

The thermal shock resistance was evaluated using the following test method: In preparation for the thermal shock resistance test, ultrasound microscopy (PVA Tepla SAM300) was first used to check whether the metal-ceramic composites were in perfect condition. For the test, only metal-ceramic composites were used that showed no delamination between the ceramic body and the metal layer or other deformations that could lead to delamination of the metal layer from the ceramic body (e.g., cracks). To test the thermal shock resistance, the metal-ceramic composites were repeatedly exposed to a cold liquid (temperature −65° C., Galden Do2TS) and a hot liquid (temperature +150° C., Galden Do2TS) in a cycling chamber (ESPEC TSB-21 51) for a period of five minutes each. The metal-ceramic composites were checked again every 1000 cycles for delamination and other deformations by means of ultrasound microscopy (PVA Tepla SAM300). The test was terminated after 3000 cycles. The metal-ceramic composites were then again examined for delamination and other deformations by means of ultrasound microscopy (PVA Tepla SAM300). The condition of the respective metal-ceramic composites after the thermal shock resistance test was compared with the condition of the metal-ceramic composites before the thermal shock resistance test with regard to delamination and other deformations. Delaminations and other deformations (e.g., cracks) were visible as white discolorations in the ultrasound image. The results were classified as follows:
Very good: No delaminations were visible
Poor: Delaminations were visible at the corners of the metal-ceramic substrate

The assessment of how completely the exposed reaction layer was removed was performed by scanning electron microscopy and EDX.

To measure the bending strength, a 3-point bending strength tool was installed in the testing machine and a corresponding test recipe according to DIN EN 843-1:2008-08 was used. The following test parameters were set: preload 0.5 N, preload speed 0.5 mm/min, test speed 10 mm/min (position controlled).

Due to the shape of the flat substrates, the sample dimensions presented here deviate from the dimensions described in the standard. Nevertheless, these parameters allow for breaking within the time specified in the standard after loading (5 to 15 seconds), so that the requirements of the standard are met. From the measured breaking forces and the sample dimensions, the breaking stress 6f was determined for each sample by means of formula 1:

$${σ}_{f} = \frac{3 \times F \times l}{2 \times b \times {h}^{2}}$$

Formula 1: Equation for calculating the breaking stress σf
   where
σf is the breaking stress (in Newton per square millimeter N×mm-2; equivalent to MPa)
F is the maximum force at break (in Newton N)
b is the width of the test specimen (in millimeters mm)
h is the height of the test specimen (in millimeters mm)
l is the distance between the centers of the support rollers (in millimeters mm)

The bending strength was classified as follows:
High: >630 MPa
Medium: 600-630 MPa
Low: <600 MPa

The results are summarized in the following table 1.

TABLE 1
Total fluences and properties of the structured metal-ceramic composites applied in the
examples

| | Total | Pulse | | Residues of the | | Thermal |
|---|---|---|---|---|---|---|
| | fluence | energy | Number of | exposed reaction | Bending | shock |
| Example | (J/cm²) | (μJ) | passes | layer | strength | resistance |
| EB-1.1 | 84 | 50 | 1 | Negligibly low | High | Very good |
| EB-1.2 | 168 | 50 | 2 | None | High | Very good |
| EB-1.3 | 168 | 100 | 1 | None | High | Very good |
| EB-1.4 | 168 | 25 | 4 | None | High | Very good |
| EB-1.5 | 336 | 50 | 4 | None | Medium | Very good |
| VB-1.1 | 42 | 25 | 1 | Almost surface- | High | Very good |
| | | | | covering | | |
| VB-1.2 | 674 | 100 | 4 | None | Low | Very good |
| EB-2.1 | 74 | 25 | 1 | Negligibly low | High | Very good |
| EB-2.2 | 148 | 50 | 1 | None | High | Very good |
| EB-2.3 | 294 | 100 | 1 | None | High | Very good |
| EB-2.4 | 294 | 25 | 4 | None | High | Very good |
| EB-2.5 | 590 | 50 | 4 | None | Medium | Very good |
| VB-2.1 | 36 | 12.5 | 1 | Almost surface- | High | Very good |
| | | | | covering | | |
| VB-2.2 | 1178 | 100 | 4 | None | Low | Very good |

| | | | | |
|---|---|---|---|---|
| VB3 | — | None | High | Inadequate |

The examples show the following:

When the exposed reaction layer was removed using the ultrashort pulse laser, the resulting metal-ceramic composites showed very good thermal shock resistance. However, complete removal of the exposed reaction layer while maintaining a high bending strength could only be achieved if the total fluence applied by the ultrashort pulse laser was within the range according to the invention (50-650 J/cm²). If the total fluence was more than 650 J/cm², this led to an impairment of the bending strength, whereas with a total fluence of less than 50 J/cm² the exposed reaction layer was not removed or was only insufficiently removed.

If the exposed reaction layer was removed by etching, the reaction layer could be completely removed without affecting the bending strength, but the resulting metal-ceramic composite showed a significant decrease in thermal shock resistance.

1. A method for structuring a metal-ceramic composite, comprising the following steps:
providing a metal-ceramic composite containing
a nitride ceramic substrate comprising a front side and a rear side,
a metal coating on the front side of the nitride ceramic substrate,
a reaction layer which is present between the metal coating and the ceramic substrate and contains one or more elements E_{RS} selected from Ti, Hf, Zr, Nb, V, Ta, and Ce,
removing the metal coating so that at least one recess is created in the metal coating and an exposed reaction layer is present in the recess,
removing the exposed reaction layer using a pulsed laser beam of an ultrashort pulse laser so that an exposed surface of the ceramic substrate is present in the recess, wherein the pulsed laser beam applies a total fluence of 50 J/cm² to 650 J/cm².

2. The method according to claim 1, wherein the nitride ceramic substrate contains a silicon nitride or an aluminum nitride and the metal coating is a copper coating or an aluminum coating.

3. The method according to claim 1 wherein the metal coating is removed by etching or laser ablation, preferably by etching.

4. The method according to claim 1 wherein the total fluence applied by the pulsed laser beam is 100 J/cm² to 320 J/cm².

5. The method according to claim 1 wherein the pulsed laser beam comprises pulses with a pulse duration of 1 femtosecond to 100 picoseconds.

6. The method according to claim 1 wherein the pulsed laser beam comprises pulses which each have a pulse energy of at least 15 μJ.

7. The method according to claim 1 wherein the pulsed laser beam has a pulse frequency f_{L} of 100 kHz to 50 MHz.

8. The method according to claim 1 wherein the pulsed laser beam hitting the exposed adhesion-promoting layer has a diameter D_{L} of 3 μm to 200 μm.

9. The method according to claim 1 wherein the pulsed laser beam satisfies the following condition:
(1−ν_{scan}/(D_{L}×f_{L}))×100%≥60%
where
ν_{scan} is the scanning speed of the pulsed laser beam,
D_{L} is the diameter of the pulsed laser beam hitting the exposed adhesion-promoting layer,
f_{L} is the pulse frequency of the pulsed laser beam.
